(19) United States
(12) Patent Application Publication
(10) Pub. No.: US 2018/0052564 A1
(43) Pub. Date: Feb. 22, 2018

(54) INPUT CONTROL APPARATUS, INPUT CONTROL METHOD, AND INPUT CONTROL SYSTEM

(71) Applicant: FUJITSU TEN LIMITED, Kobe-shi (JP)

(72) Inventor: Tomohisa KOSEKI, Kobe-shi (JP)

(73) Assignee: FUJITSU TEN LIMITED, Kobe-shi (JP)

(21) Appl. No.: 15/672,416

(22) Filed: Aug. 9, 2017

(30) Foreign Application Priority Data
Aug. 18, 2016 (JP) 2016-160504

(51) Int. Cl. G06F 3/041; G06F 3/0488; H01L 41/04

(52) U.S. Cl. CPC G06F 3/0418; H01L 41/04; G06F 3/0488; G06F 3/0412

(57) ABSTRACT

An input control apparatus receives a touch operation of a user. The input control apparatus includes a storage unit that stores an actual touch operation position where a touch operation was performed with a predetermined position on an input apparatus as a target, and a correction unit that corrects, based on a relationship between the actual touch operation position stored in the storage unit and the predetermined position, at least one of an input value at a time of reception of a touch operation for an operation target displayed on a display apparatus and a display content corresponding to the touch operation.

### CROSS-REFERENCE TO RELATED APPLICATION

This application is based upon and claims the benefit of prior Japanese Patent Application No. 2016-160504 filed on Aug. 18, 2016, the entire contents of which are incorporated herein by reference.

### FIELD

The present invention relates to an input control apparatus, an input control method, and an input control system.

### BACKGROUND

Conventionally, there is known an input control apparatus which is connected to an input device, such as a touch pad or a touch panel, which detects coordinates of a contact position of an operation finger or the like of an operator (hereinafter also referred to as a user) which is in contact with a device surface. Based on the contact position detected by the input device, the input control apparatus allows reception of a contact operation intended by the user with respect to contents displayed on a display apparatus including a display device, such as a liquid crystal display (LCD), which is connected to the input control apparatus, for example. Also, based on a track of the contact position detected by the input device, the input control apparatus allows display of an input character intended by the user on the display apparatus, or reception of screen scrolling of an image or the like displayed on the display apparatus, for example.

In recent years, there is proposed a technology of causing the surface of an input device that detects a contact position to vibrate so as to provide a predetermined tactile sensation to an operation finger of the user in contact with the surface. With the technology of providing the tactile sensation, a tactile sensation of minute unevenness of as if tracing over sand or the like with a fingertip (rough sensation) maybe provided or a tactile sensation that is smooth to the fingertip that is in contact with the surface of the input device (smooth sensation) may be provided based on the level of vibration frequency, for example. By combining the above-mentioned technology of providing a tactile sensation with the input device that detects a contact position, the input control apparatus may provide a sensation of switch operation or a sensation of button operation with respect to a graphical user interface (GUI) element displayed on the display device used in combination with the input device, for example.

Additionally, as a prior art document describing a technology related to the technology described in the present specification, there is the following patent document.

[Patent document 1] Japanese Patent Laid-Open No. 2013-122777

### SUMMARY

### Technical Problem

For example, the technology of providing a tactile sensation described above may be effectively used with respect to so-called touch-type operation input of performing an operation input without looking at the surface of an input device. For example, if an operation finger or the like that is placed in contact without the user looking at the surface of the input device deviates from a predetermined operation region, the user may be notified to the effect by a change in the tactile sensation. The user is enabled to perform a contact operation on an image or the like displayed on the screen of a display apparatus which is visually separated from the input device, by performing a contact operation on the input device without taking his/her eyes off the screen displayed on the display apparatus, for example.

The way a user performing touch-type operation input moves the operation finger tends to be have a manner unique to the user performing the operation. Accordingly, at the input control apparatus receiving input by the touch-type operation, the operation contents (operation position, operation track, etc.) intended by a user and the operation contents detected via the input device are possibly deviated from each other. For example, in some cases, the input control apparatus detects a contact on a GUI element displayed on the display apparatus based on an operation of a user A, but does not detect a contact on the GUI element based on an operation of a user B. The present invention is for enabling an operation input intended by a user, and for increasing convenience.

### Solution to Problem

An aspect of the technology of the disclosure is exemplified by an input control apparatus. That is, the input control apparatus receives a touch operation of a user. The input control apparatus includes a storage unit that stores a touch operation position where a touch operation was performed with a predetermined position on an input apparatus as a target, and a correction unit that corrects, based on a relationship between the touch operation position stored in the storage unit and the predetermined position, at least one of an input value at a time of reception of a touch operation for an operation target displayed on a display apparatus and a display content corresponding to the touch operation.

### Advantageous Effect of Invention

According to the present input control apparatus, an operation input intended by a user is enabled, and convenience of operation input is increased.

### BRIEF DESCRIPTION OF THE DRAWINGS

FIG. 1 is a diagram illustrating an example configuration of an input control system;

FIG. 2A is a diagram describing an input control function provided by an input control apparatus, and is an explanatory diagram for movement of an operation finger on a touch pad as envisioned by a user performing a touch-type operation;

FIG. 2B is a diagram describing the input control function provided by the input control apparatus, and is a diagram describing a movement track of the operation finger at the time of a touch-type operation detected via the touch pad;

FIG. 2C is a diagram describing the input control function provided by the input control apparatus, and is a diagram describing an operation position or an operation track that is displayed on a display according to a touch-type operation;

FIG. 3 is a diagram illustrating an example of a touch pad having a protruding structure enabling fingerprint authentication;

FIG. 4 is a diagram illustrating an example of a hardware configuration of the input control apparatus;

FIG. 5 is a diagram describing an operation correction process; FIG. 6A illustrates an example of a scenario of a case of performing coordinate correction on an operation in each of a left-right direction and an up-down direction;

FIG. 6B illustrates an example of a scenario of a case of performing coordinate correction on an operation in each of a left-right direction and an up-down direction;

FIG. 7 illustrates an example of a scenario of a case of using, for operation correction, a display element that is associated with function control for an AVN device;

FIG. 8 illustrates an example of a scenario of a case of using, for operation correction, a map screen called up by a navigation function of the AVN device;

FIG. 9A illustrates an example of a scenario of a case of performing coordinate correction with respect to a movable range of an operation finger;

FIG. 9B illustrates an example of a scenario of a case of performing coordinate correction with respect to a movable range of an operation finger;

FIG. 10 illustrates an example of a scenario of a case of using a correction reference character for operation correction; and

FIG. 11 is a flowchart illustrating an example of an operation correction process of the input control apparatus of the present embodiment.

### DESCRIPTION OF EMBODIMENTS

Hereinafter, an input control apparatus according to an embodiment will be described with reference to the drawings. The configuration of the following embodiment is only an example, and the present input control apparatus is not limited to the configuration of the embodiment.

<1. System Configuration>

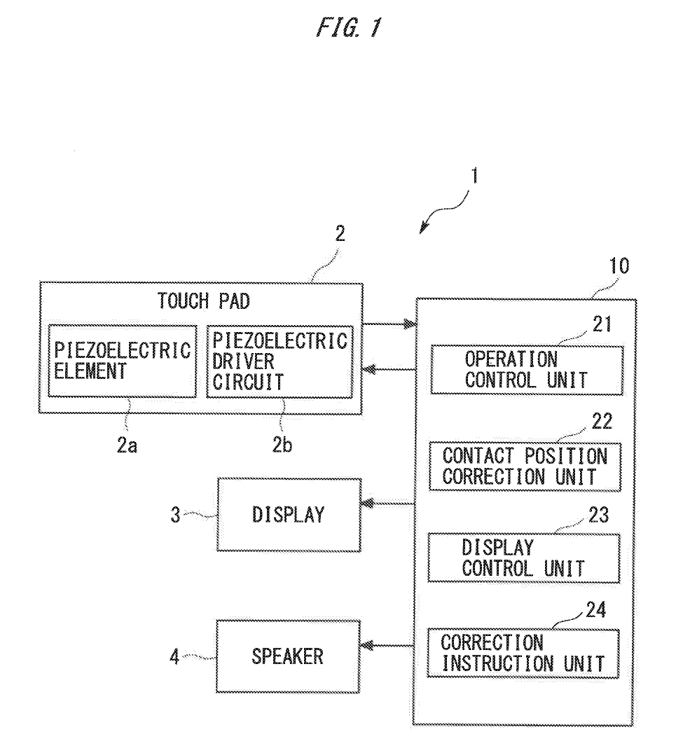

FIG. 1 is a diagram illustrating an example of a configuration of an input control system according to the present embodiment. The input control system illustrated in FIG. 1 is an example of application to a general vehicle (hereinafter also referred to as a vehicle) such as a sedan or a wagon. In a vehicle on which the input control system is mounted, the input control apparatus according to the present embodiment configures a part of a vehicle-mounted audio-visual-navigation integrated device (hereinafter also referred to as an AVN device), for example. Alternatively, the input control apparatus may be connected to an external appliance interface provided to a vehicle-mounted AVN device so as to provide the function of the input control apparatus of the present embodiment. As the mode of the input control apparatus that is connected to an external appliance interface provided to the vehicle-mounted AVN device, an information processing apparatus such as a smartphone, a personal computer (PC), or a personal digital assistant (PDA) maybe cited. In the following, the function provided by the input control apparatus of the present embodiment will be described as an example of the mode of the input control system illustrated in FIG. 1.

An input control system 1 illustrated in FIG. 1 includes a touch pad 2, a display 3, a speaker 4, and an input control apparatus 10, which are connected to one another. The touch pad 2, the display 3, and the speaker 4 connected to the input control apparatus 10 may configure a part of an AVN device. Additionally, in a vehicle on which the input control system 1 is mounted, the touch pad 2 is arranged at a center console or the like while exposing a device surface for detecting a contact operation on the touch pad 2 so that a contact operation of a user can be detected, for example. Also, the display 3 is arranged at a position, such as a cockpit panel, different from the arranged position of the touch pad 2, for example. Alternatively, in a vehicle on which the input control system 1 is mounted, the display 3 may configure a head-up display according to which display contents are shown on the windshield, on the inside of the vehicle, for example.

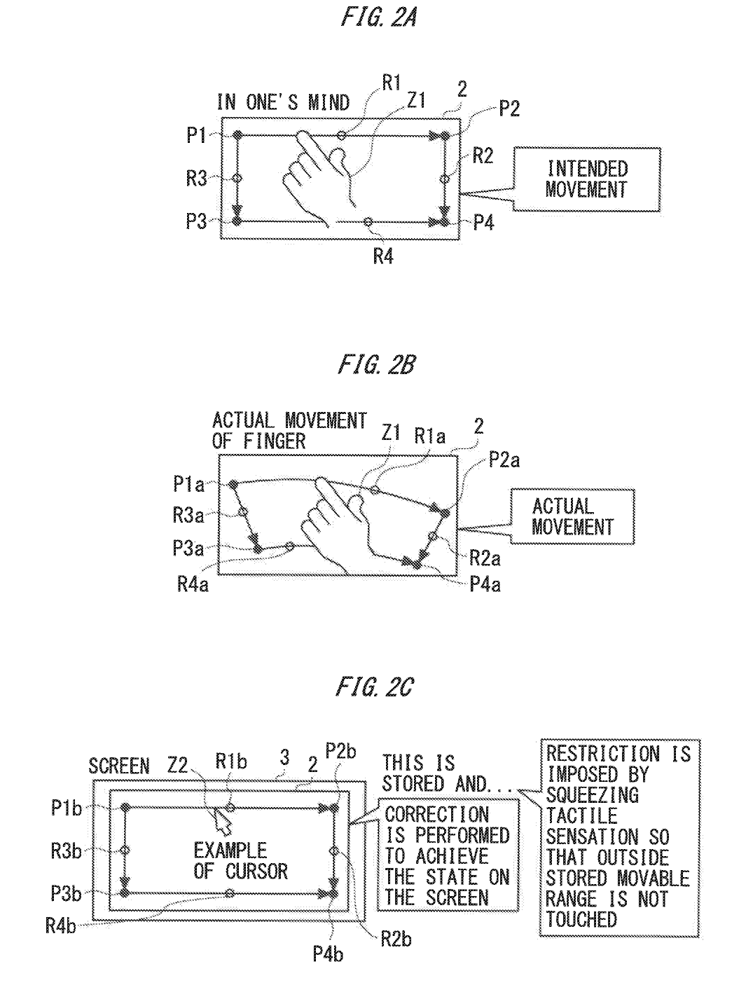

FIGS. 2A to 2C are diagrams describing an input control function provided by the input control apparatus 10 of the present embodiment. For example, the input control apparatus 10 of the present embodiment performs input control such that an operation position or an operation track based on a touch-type operation input via the touch pad 2 becomes an operation input that is intended by a user on the screen of the display 3. According to the input control function provided by the input control apparatus 10 of the present embodiment, the manner of movement of an operation finger unique to each user performing a touch-type operation may be may be corrected. According to the input control apparatus 10 of the present embodiment, a deviation of an operation on the screen of the display 3 due to a unique manner of movement of an operation finger at the time of a touch-type operation may be suppressed. The input control system 1 including the input control apparatus 10 enables an operation input intended by the user, and may increase convenience of operation input at the time of a touch-type operation.

FIG. 2A is an explanatory diagram for the manner of movement of an operation finger Z1 as envisioned by a user performing a touch-type operation on the touch pad 2. For example, a user performing a touch-type operation is a user seated in the driver's seat, and is assumed to operate the touch pad 2 arranged at the center console with the left hand. Also, in FIG. 2A, the user performing a touch-type operation is assumed to be moving the operation finger Z1 along a rectangular outer shape of the touch pad 2, for example.

For example, the user performing the touch-type operation moves the operation finger Z1 based on an idea of following routes R1, R2, R3, R4, and performs a movement operation along the rectangular outer shape of the touch pad 2. The route R1 is an envisioned route extending from envisioned coordinates P1 corresponding to the upper left corner portion of the touch pad 2 to envisioned coordinates P2 corresponding to the upper right corner portion of the touch pad 2, for example. In the same manner, the route R2 is an envisioned route extending from the envisioned coordinates P2 corresponding to the upper right corner portion of the touch pad 2 to envisioned coordinates P4 corresponding to the lower right corner portion of the touch pad 2, and the route R3 is an envisioned route extending from the envisioned coordinates P1 corresponding to the upper left corner portion of the touch pad 2 to envisioned coordinates P3 corresponding to the lower left corner portion of the touch pad 2. The route R4 is an envisioned route extending from the envisioned coordinates P3 corresponding to the lower left corner portion of the touch pad 2 to the envisioned coordinates P4 corresponding to the lower right corner portion of the touch pad 2.

FIG. 2B is a diagram describing a movement track of the operation finger Z1 at the time of a touch-type operation detected via the touch pad 2. The user performing the touch-type operation moves the operation finger Z1 according to the idea as described with reference to FIG. 2A, without looking at the contact position of the operation finger Z1 that is in contact with the surface (device surface) of the touch pad 2. Accordingly, the movement track of the operation finger Z1, at the time of the touch-type operation, detected by the touch pad 2 follows routes different from the envisioned routes R1-R4 illustrated in FIG. 2A. For example, a movement that is track detected at the time of a touch-type operation reflects a manner of movement that is unique to each user performing a contact operation by using the touch pad 2.

For example, the actual movement track of the operation finger Z1 envisioned to be parallel to an upper end portion of the touch pad 2 is detected as an arc-shaped curved route R1a extending from coordinates P1a as the starting position to coordinates P2a. In the same manner, the actual movement track for the envisioned route R2 envisioned to be parallel to a right end portion of the touch pad 2 is detected as an oblique route R2a extending from the coordinates P2a as the starting position to coordinates P4a. The actual movement track for the envisioned route R3 envisioned to be parallel to a left end portion of the touch pad 2 is detected as an oblique route R3a extending from the coordinates P1a as the starting point to coordinates P3a. Also, the actual movement track of the operation finger Z1 envisioned as the route R4 parallel to a lower end portion of the touch pad 2 is detected as an arc-shaped curved route R4a extending from the coordinates P3a as the starting position to the coordinates P4a.

When comparing the envisioned routes R1-R4 illustrated in FIG. 2A with the tracks of the routes R1a-R4a actually detected via the touch pad 2, it can be seen that the following unique manner is apparent in the manner of movement of the operation finger Z1 at the time of the touch-type operation of the user. For example, according to comparison between the envisioned routes R1, R4 and the routes R1a, R4a, movement in the left-right direction tends to become arc-shaped, and the contact position of the operation finger Z1 tends to deviate downward as it gets nearer to the right end side. Also, for example, according to comparison between the envisioned routes R2, R3 and the routes R2a, R3a, movement in the up-down direction tends to become oblique, and the contact position of the operation finger Z1 on the left end side tends to deviate in the right direction as it moves downward. Also, with respect to the movement in the up-down direction on the right end side, the contact position of the operation finger Z1 tends to deviate in the left direction as it moves downward.

In the same manner, when comparing positional relationships of the envisioned coordinates P1-P4 illustrated in FIG. 2A to the coordinates P1a-P4a, which are the actual contact positions, it can be seen that the coordinates P1a-P4a, which are the actual contact positions, are detected within a rectangle defined by the envisioned coordinates P1-P4 and the envisioned routes R1-R4. Also, it can be seen that the space between the coordinates P1a and P2a detected on the upper side of the touch pad 2 is greater than the space between the coordinates P3a and P4a detected on the lower side of the touch pad 2.

The input control function provided by the input control apparatus 10 of the present embodiment stores a correction value for the unique manner of each user regarding the manner of movement of the operation finger in the up-down direction and the left-right direction described above. For example, the input control apparatus 10 performs input control such that an operation position or an operation track based on a touch-type operation input via the touch pad 2 becomes, on the screen of the display 3, an operation input that is intended by the user. The operation position or the operation track subjected to the input control so as to achieve an operation input intended by the user is reflected in the display position of a GUI element, such as a pointer, displayed on the display 3, for example. According to the input control apparatus 10 of the present embodiment, control of display contents is performed based on the operation position or the operation track which has been subjected to input control so as to achieve an operation input intended by the user.

According to the input control apparatus 10 of the present embodiment, an operation is performed on an operation target (operation object) displayed on the display 3, based on an operation position or an operation track based on a touch-type operation input via the touch pad 2. The input control apparatus 10 performs display control regarding sound volume, air conditioner, content reproduction, navigation destination setting, content selection and the like presented via the AVN device, based on an operation position or an operation track after correction, for example. Also, the input control apparatus 10 controls an input value regarding an amplifier for increasing or decreasing the sound volume, air conditioner or the like based on an operation position or an operation track after correction, for example.

FIG. 2C is a diagram describing an operation position or an operation track that is displayed on the display 3 according to a touch-type operation. Additionally, FIG. 2C illustrates an example of the operation position or the operation track that is displayed on the screen of the display 3 in a case where a rectangular operation track is drawn along the outer frame of the touch pad 2 illustrated in FIG. 2B, for example. On the display screen, in FIG. 2C, displayed on the display 3, Z2 is a GUI element indicating the contact position of the operation finger Z1 detected by the touch pad 2 according to a touch-type operation. A cursor is indicated as an example of the GUI element indicating the contact position of the operation finger Z1 detected by the touch pad 2.

As illustrated in FIG. 2C, the input control apparatus 10 performs correction such that the coordinates P1a-P4a described with reference to FIG. 2B are positioned at display coordinates P1b-P4b in accordance with the size of the display region of the display 3, and displays the coordinates. Then, the input control apparatus 10 performs correction so as to cause the routes R1a-R4a described with reference to FIG. 2B to become routes R1b-R4b, and displays the routes. As illustrated in FIG. 2C, the route R1a detected based on a touch-type operation is displayed as the straight route R1b connecting the display coordinates P1b and P2b, for example. In the same manner, the route R2a is displayed as the straight route R2b connecting the display coordinates P2b and P4b, the route R3a as the straight route R3b connecting the display coordinates P1b and P3b, and the route R4a as the straight route R4b connecting the display coordinates P3b and P4b.

The routes R1a, R4a detected by the touch pad 2 as arc-shaped curves are displayed as the straight routes R1b, R4b that are parallel along the rectangular outer frame of the display 3, respectively. Also, the oblique routes R2a, R3a detected by the touch pad 2 are displayed as straight routes R2b, R3b that are parallel along the rectangular outer frame of the display 3.

The instruction accuracy, regarding a GUI element displayed on the display 3, of a user performing a touch-type operation on the touch pad 2 while looking at the display position of the cursor Z2 displayed on the display 3 may be increased based on the operation track of the operation finger Z1 corrected under the control of the input control apparatus 10. According to the input control system 1 including the input control apparatus 10, a deviation between operation contents (operation position, operation track, etc.) intended by the user and the operation contents detected by the touch pad 2 based on a touch-type operation is suppressed.

Referring back to FIG. 1, the touch pad 2 is an input device that detects the coordinates of a contact position of the operation finger Z1 or the like of a user in contact with the device surface. A contact position detected by the touch pad 2 functions as a pointing device for indicating the display position of a GUI element or the like displayed on the display 3, for example. A contact position of the operation finger Z1 or the like detected by the touch pad 2 may be expressed in two-dimensional coordinates (X, Y) taking the left-right direction as an X-axis and the up-down direction as a Y-axis with the upper left corner portion of the touch pad 2 as the origin, for example.

Coordinates of a contact operation detected by the touch pad 2 are output to the input control apparatus 10 at a specific cycle of 10 ms, for example. Additionally, association between the display region of the display 3 and coordinates detected via the touch pad 2 is performed by the input control apparatus 10, for example. The input control apparatus 10 may perform control by taking the upper left corner portion of the display device, such as an LCD, forming the display 3 as the origin, and performing scaling on the two-dimensional coordinates (X, Y) detected by the touch pad 2 according to the size of the display region of the display 3, so as to achieve a one-to-one coordinate relationship, for example. The X-axis, which is the left-right direction of the touch pad 2, corresponds to the left-right direction of the display region of the display 3, and the Y-axis, which is the up-down direction of the touch pad 2, corresponds to the up-down direction of the display region of the display 3.

Furthermore, the touch pad 2 is an input device that causes the surface of the device where a contact position is to be detected to vibrate, and to provide a predetermined tactile sensation, such as a rough sensation or a smooth sensation, to the operation finger Z1 of the user. In order to provide the tactile sensation to the operation finger Z1 or the like in contact with the device surface, the touch pad 2 includes a piezoelectric element such as a piezoelectric element 2a, and a piezoelectric driver circuit 2b that applies a predetermined voltage to the piezoelectric element 2a. The piezoelectric element 2a is arranged in contact with a rear surface of the device for detecting a contact position on the touch pad 2, for example.

Generally, a fingertip is known to detect, as a tactile sensation, a vibration frequency of vibration at a frequency of about 0 Hz to 300 Hz. The touch pad 2 may give a tactile sensation to the operation finger Z1 of the user in contact with the surface of the device by causing the piezoelectric element 2a, which is the piezoelectric element arranged in contact with the rear surface of the device for detecting a contact position, to vibrate by the piezoelectric driver circuit 2b. For example, the touch pad 2 may provide a rough sensation of as if tracing over sand with a fingertip, by controlling, via the piezoelectric driver circuit 2b, the value of voltage to be applied to the piezoelectric element 2a so as to achieve vibration at a frequency of about 50 Hz. Moreover, for example, the touch pad 2 may provide a smooth tactile sensation by controlling, via the piezoelectric driver circuit 2b, the value of voltage to be applied to the piezoelectric element 2a so as to achieve vibration at a frequency of about 300 Hz.

For example, the input control apparatus 10 may provide a tactile sensation according to the contact position of the operation finger Z1 detected via the touch pad 2, by controlling, via the piezoelectric driver circuit 2b, the value of voltage to be applied to the piezoelectric element 2a and changing the level of the vibration frequency according to the contact position. For example, if a contact position during a touch-type operation is within a predetermined range, the input control apparatus 10 increases the vibration frequency to about 300 Hz to provide a smooth sensation. On the other hand, if a contact position during a touch-type operation deviates from the predetermined range, the input control apparatus 10 reduces the vibration frequency to about 50 Hz to provide a rough sensation. The predetermined range here is a contact region that is associated in advance with the size of the display region of the display 3, for example. A user performing a touch-type operation is enabled to perform a contact operation within the predetermined range set in advance, based on the tactile sensation on the operation finger Z1 in contact with the device surface of the touch pad 2.

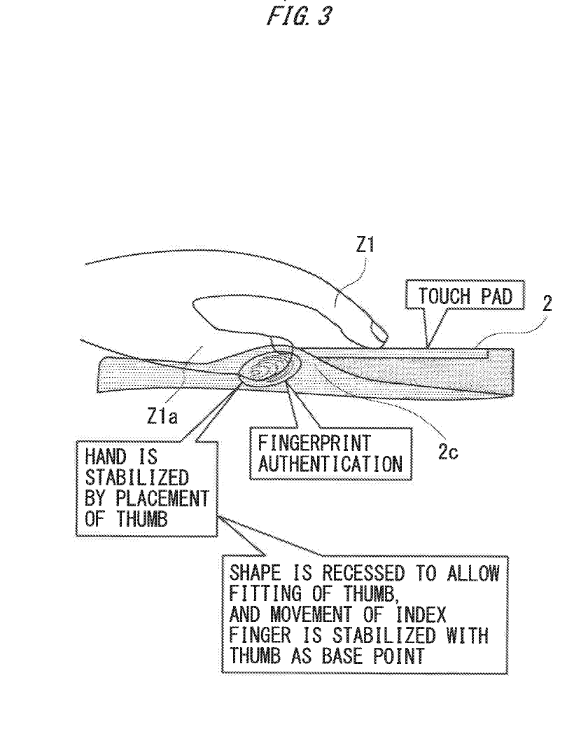

Additionally, the touch pad 2 may include a structure for identifying a user performing a contact operation. As a structure of the touch pad 2 for identifying a user, a structure capable of fingerprint authentication may be cited as an example. FIG. 3 illustrates an example of the touchpad 2 having a protruding structure enabling fingerprint authentication. A protruding structure 2C illustrated in FIG. 3 is provided on a right side surface of the device for detecting a contact position on the touch pad 2, for example. Inside the protruding structure 2C, appliances for performing fingerprint authentication, such as an illumination apparatus and an image capturing apparatus, such as a camera, are provided.

The protruding structure 2C in FIG. 3 is provided near a lower right corner portion of a contact detection region of the touch pad 2 arranged at the center console, for example . For example, a user seated in the driver's seat performs a touch-type operation by placing a left thumb Z1a on the protruding structure 2C provided, to the touch pad 2 arranged at the center console, near the lower right corner portion. A touch-type operation on the touch pad 2 is performed by an operation finger Z1 other than the left thumb Z1a, for example.

With the touch pad 2, by providing, near the lower right corner portion of the contact detection region, the protruding structure 2C where the left thumb Z1a is to be placed, the contact position of the operation finger Z1 at the time of performing a touch-type operation is expected to become stable with the left thumb Z1a as a base point (support point). With the touch pad 2, operation accuracy at the first contact position at the time of performing a touch-type operation is expected to be increased. Additionally, the protruding structure 2C may be provided in an integrated manner with the touch pad 2, or may be provided on the center console where the touch pad 2 is arranged. In the case of providing the protruding structure 2C to the center console, the protruding structure 2C may be arranged so as to be positioned near the lower right corner portion of the contact detection region of the touch pad 2.

The surface of the protruding structure 2C, where the left thumb Z1a is to contact, has a recessed shape so that the left thumb Z1a of the user in contact is comfortably fitted, and a hole that is used for performing fingerprint authentication may be provided near a center portion of the recessed shape. The illumination apparatus of an authentication appliance embedded inside the protruding structure 2C radiates on the left thumb Z1a in contact, through the hole, light (such as ultraviolet rays or infrared rays) for capturing a fingerprint image, and the image capturing apparatus, such as a camera for authentication, captures the fingerprint of the left thumb Z1a of the user which is irradiated with the light. The fingerprint captured by the camera for authentication or the like is output to the input control apparatus 10, for example. The input control apparatus 10 may store the fingerprint image captured by the camera for authentication or the like in a memory or the like, in association with a coordinate correction value for a unique manner of movement of the operation finger Z1. For example, the input control apparatus 10 checks a fingerprint image stored in the memory and a fingerprint image captured by the camera for authentication against each other, and specifies the user performing the contact operation. Then, the input control apparatus 10 reads out the coordinate correction value for the unique manner of movement of the operation finger Z1 associated with the fingerprint image of the user performing the contact operation, and performs correction described with reference to FIG. 2C.

Additionally, as other methods for identifying a user performing a contact operation, there may be cited iris authentication, voice authentication, and password authentication, for example. The input control system 1 of the present embodiment may include an authentication appliance according to the authentication method for identifying a user performing a contact operation. For example, in the case of using iris authentication, the input control system 1 may include, at the rearview mirror or the like in the vehicle, appliances such as an illumination apparatus and an image capturing apparatus, such as a camera, for capturing an iris image of a user seated in the driver's seat. Also, in the case of using voice authentication, the input control system 1 may include an appliance such as a microphone for receiving voice input. Moreover, in the case of performing password authentication, the input control system 1 may display a GUI element for receiving password input on the display 3. In the case of performing password authentication, the input control system 1 may read out a password recorded in a removable recording medium, such as an USB memory, to identify a user performing a contact operation.

Referring back to FIG. 1, the display 3 outputs data processed by the input control apparatus 10, various types of contents, such as images, provided via the input control system 1, and the like. As various types of contents provided via the input control system 1, there maybe cited navigation or television (TV) broadcast presented by the AVN device, reproduced images reproduced from a digital versatile disk (DVD) or a Blu-ray Disc (BD (registered trademark)), and the like. The display 3 includes a display device such as an LCD, an electroluminescence (EL) panel, or an organic EL panel. Additionally, for example, the display 3 may include a device for detecting a contact position of an operation finger or the like in contact with the surface of the display device, such as the LCD, so as to function as a touch panel. By including the touch panel function, the display 3 enables a contact operation on a GUI element displayed in the display region of the display device, for example.

The speaker 4 is an output device that outputs data processed by the input control apparatus 10, a sound signal provided via the input control system 1, and the like in the form of sound. The speaker 4 may be constituted of a plurality of speakers.

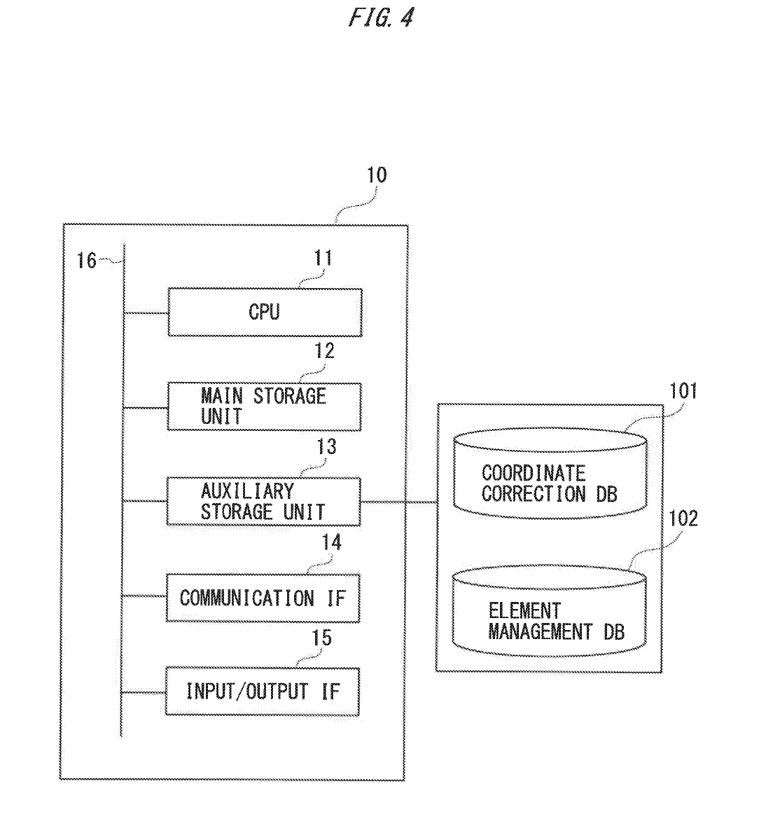

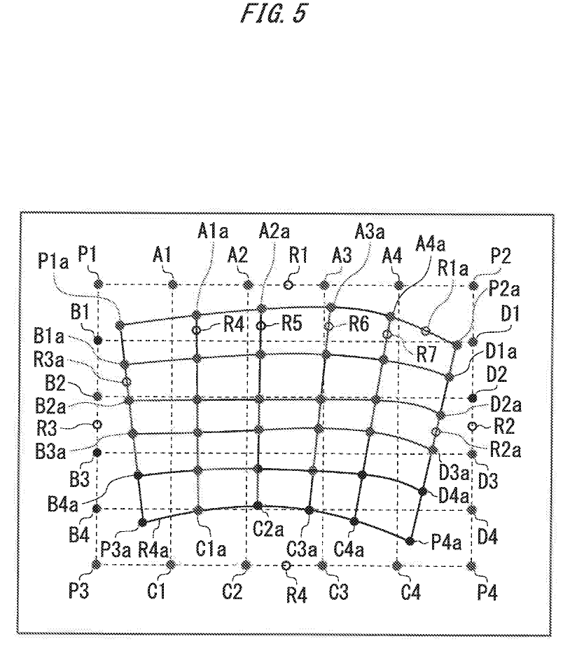

FIG. 4 is a diagram illustrating an example of a hardware configuration of the input control apparatus 10. As illustrated in FIG. 4, the input control apparatus 10 includes a central processing unit (CPU) 11, a main storage unit 12, an auxiliary storage unit 13, a communication interface (IF) 14, and an input/output IF 15, which are interconnected by a connection bus 16. The CPU 11 is a central processing apparatus that controls the entire input control apparatus 10. The CPU 11 is referred to also as a processor. However, the CPU 11 is not limited to a single processor, and may have a multi-processor configuration. Also, a single CPU 11 connected by a single socket may have a multi-core configuration. The CPU 11 loads a program stored in the auxiliary storage unit 13 into the work area of the main storage unit 12 in an executable manner and controls a peripheral appliance through execution of the program to thereby provide a function matching a predetermined objective.

The main storage unit 12 is a storage medium where the CPU 11 caches programs and data, and where a work area is to be developed. For example, the main storage unit 12 includes a flash memory, a random access memory (RAM), and a read only memory (ROM). The auxiliary storage unit 13 is a storage medium that stores programs to be executed by the CPU 11, operation setting information, and the like. The auxiliary storage unit 13 is a hard-disk drive (HDD), a solid state drive (SSD), an erasable programmable ROM (EPROM), a flash memory, a USB memory, a secure digital (SD) memory card, or the like, for example. The communication IF 14 is an interface to a network or the like connected to the input control apparatus 10. The input/output IF 15 is an interface for input/output of data to/from a sensor or an appliance connected to the input control apparatus 10. At the input control system 1, control of input/output of data to/from the touch pad 2, the display 3, and the speaker 4 is performed via the input/output IF 15. Additionally, the structural elements described above may each be provided in plurality, or one or some of the structural elements may be omitted. Also, the structural elements described above may be included as the structural elements of the AVN device.

The input control apparatus 10 provides each of processing units illustrated in FIG. 1, namely, an operation control unit 21, a contact position correction unit 22, a display control unit 23, and a correction instruction unit 24, by execution of programs by the CPU 11. However, at least a part of processes by the processing units mentioned above may be provided by a digital signal processor (DSP), an application specific integrated circuit (ASIC), or the like. Also, at least one or some of the processing units mentioned above may be dedicated large scale integrations (LSI), such as field-programmable gate arrays (FPGA), or other digital circuits. Moreover, an analog circuit may be included at least as a part of the processing units mentioned above. The input control apparatus 10 includes, in the auxiliary storage unit 13, a coordinate correction DB 101 and an element management DB 102 to be referred to by the processing units mentioned above or as storage destinations of managed data.

The operation control unit 21 in FIG. 1 receives coordinates of a contact position, detected via the touch pad 2, of an operation finger Z1 of a user performing a touch-type operation. The coordinates of a contact operation detected by the touch pad 2 are output to the input control apparatus 10 at a specific cycle of 10 ms, for example. The operation control unit 21 receives the coordinates of a contact position at the specific cycle, and temporarily stores the coordinates in a predetermined region in the main storage unit 12. Changes in the coordinates of a contact position received at the specific cycle form a time-series track according to an operation moving on the touch pad 2.

Also, in the case where the touch pad 2 includes the protruding structure 2C for performing fingerprint authentication, as described with reference to FIG. 3, the operation control unit 21 acquires a fingerprint image of a user acquired via the protruding structure 2C. The operation control unit 21 stores the acquired fingerprint image, in the main storage unit 12, in association with a change in the coordinates of the contact position on a time axis . The operation control unit 21 transfers the acquired fingerprint image and the coordinate position of the contact position to the contact position correction unit 22.

Additionally, the operation control unit 21 may detect a glance of a user performing a contact operation on the touch pad 2, and may determine that the detected contact operation is a touch-type operation. As a glance detection sensor, an infrared radiation apparatus provided to the rearview mirror in the vehicle, an image capturing apparatus, such as a camera, or a combination thereof may be cited. For example, at the time of performance of correction described with reference to FIGS. 2A and 2B, the detection accuracy for specifying a manner, at the time of a contact operation, unique to a user may be increased by the operation control unit 21 determining a touch-type operation.

Also, in the case where a contact operation received after performance of correction described with reference to FIGS. 2A and 2B is performed outside a predetermined range of region, the operation control unit 21 controls the piezoelectric driver circuit 2b so as to change a tactile sensation provided to the operation finger Z1. The operation control unit 21 changes the tactile sensation provided to the operation finger Z1 by changing the level of the vibration frequency of the piezoelectric element 2a by controlling the piezoelectric driver circuit 2b. The user performing a touch-type operation using the touch pad 2 changes the contact position according to a change in the tactile sensation on the operation finger Z1, and thus, a contact operation within a predetermined range set in advance is enabled. The input control apparatus 10 may suppress occurrence of an erroneous operation performed outside a predetermined range of region.

The contact position correction unit 22 performs operation correction regarding a manner of movement of the operation finger Z1 unique to the user, based on the coordinates of the contact position based on the touch-type operation and a change over time in the coordinates transferred from the operation control unit 21. Operation correction is performed according to the contents of a correction operation instruction issued to the user via the speaker 4 or the display 3, for example.

FIG. 5 is a diagram describing an operation correction process performed by the contact position correction unit 22. For example, FIG. 5 illustrates an example of a correction process for a case of indicating a contact operation along a maximum outer shape of the touch pad 2, and correcting the detected operation track. In FIG. 5, P1-P4 are envisioned coordinates in an operation region of the touch pad 2. Routes R1a-R4a indicated by thick solid lines are the track (operation track) of contact coordinates detected via the touch pad 2. The route R1a is an arc-shaped curve extending from coordinates P1a as the base point to coordinates P2a. The route R2a is an oblique line extending from the coordinates P2a as the base point to coordinates P4a. The route R3a is an oblique line extending from the coordinates P1a as the base point to coordinates P3a. The route R4a is an arc-shaped curve extending from the coordinates P3a as the base point to the coordinates P4a. Additionally, the routes R1-R4 are the same as those in FIG. 2A.

For example, the contact position correction unit 22 performs coordinate correction in such a way that the coordinates P1a overlap the envisioned coordinates P1, the coordinates P2a overlap the envisioned coordinates P2, the coordinates P3a overlap the envisioned coordinates P3, and the coordinates P4a overlap the envisioned coordinates P4.

For example, the contact position correction unit 22 equally divides the rectangular region defined by the envisioned coordinates P1-P4 into a plurality of regions. FIG. 5 illustrates an example where the rectangular region defined by the envisioned coordinates P1-P4 is equally divided into five in both the left-right direction and the up-down direction. In the same manner, the contact position correction unit 22 divides the region including the coordinates P1a-P4a and defined by the routes R1a-R4a into the same number of regions as the number of equally divided regions of the correction-destination rectangular region.

For example, the contact position correction unit 22 equally divides the route R1a extending from the coordinates P1a as the base point to the coordinates P2a into five. Also, the contact position correction unit 22 equally divides the route R4a extending from the coordinates P3a as the base point to the coordinates P4a into five. Furthermore, the contact position correction unit 22 connects division points of the equally divided route R1a with corresponding division points of the equally divided route R4a by routes R4-R7 in order from the left end side.

Moreover, the contact position correction unit 22 equally divides, into five, the route R3a extending from the coordinates P1a as the base point to the coordinates P3a, and the route R2a extending from the coordinates P2a as the base point to the coordinates P4a. Furthermore, the contact position correction unit 22 equally divides each of the routes R4-R7 into five. Then, the contact position correction unit 22 connects the division points of the equally divided route R3a with corresponding division points of the equally divided route R2a by curved lines, through the respective division points of the routes R4-R7, in order from the upper end side. The region including the coordinates P1a-P4a and defined by the routes R1a-R4a becomes a meshed region which is divided into 25 regions, which is the same as the number of equally divided regions of the correction-destination rectangular region.

For example, the contact position correction unit 22 calculates coordinate correction amounts by which the coordinates P1a, A1a, A2a, A3a, A4a, P2a are made the coordinates P1, A1, A2, A3, A4, P2, respectively, and associates the calculated coordinate correction amounts with the coordinates P1a, A1a, A2a, A3a, A4a, P2a. In the same manner, the contact position correction unit 22 calculates coordinate correction amounts by which the coordinates B1a, B2a, B3a, B4a, P3a are made the coordinates B1, B2, B3, B4, P3, respectively, and associates the calculated coordinate correction amounts with the coordinates B1a, B2a, B3a, B4a, P3a. The same thing can be said for coordinates C1-C4 and coordinates C1a-C4a, coordinates D1-D4 and coordinates D1a-D4a, and the coordinates P4 and the coordinates P4a.

The contact position correction unit 22 performs the process described above on a correction-destination meshed region corresponding to the equally divided meshed region, and performs association of coordinate correction amounts. As a result, the coordinate correction amount is associated with each division point of the region which is defined by the routes R1a-R4a and which is divided into 25 regions. The contact position correction unit 22 stores the coordinates P1a-P4a and the division points associated with the coordinate correction amounts in the coordinate correction DB 101, in association with user identification information (fingerprint image, voiceprint, iris image, password, etc.). Also, the contact position correction unit 22 transfers coordinate information about a contact position after correction to the display control unit 23.

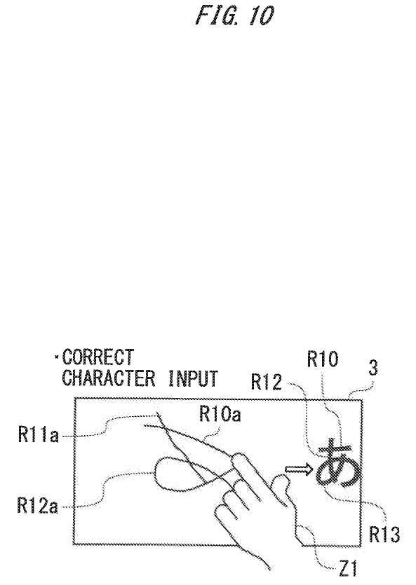

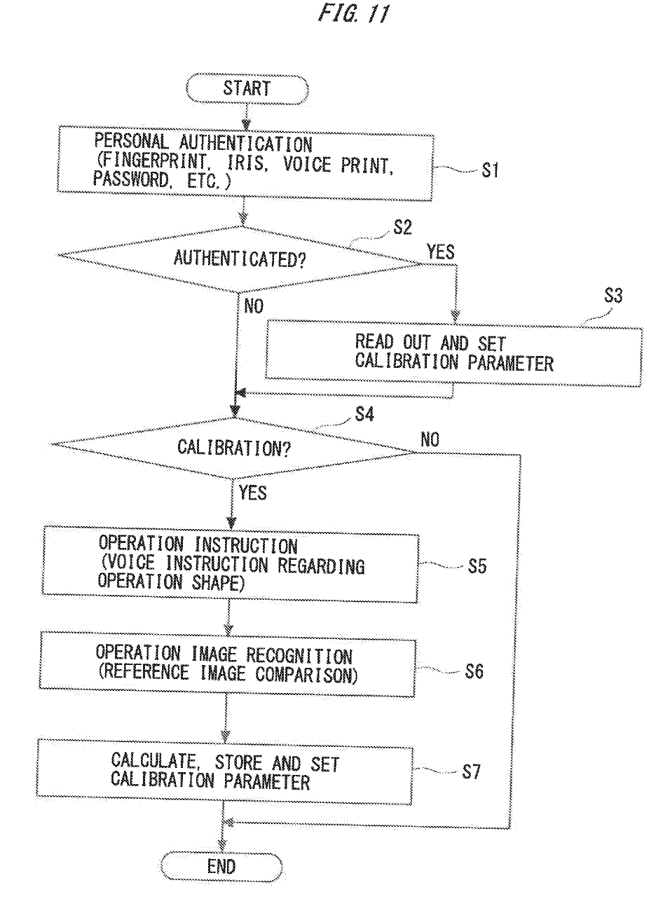

Additionally, at the time of storing the information in the coordinate correction DB 101, the contact position correction unit 22 may store, in association, time information of performance of coordinate correction. Also, the contact position correction unit 22 may include, in the information to be stored in the coordinate correction DB 101, identification information for identifying a scenario pattern for performing correction as described below with reference to Figs . 6A and 6B to FIG. 10. The input control apparatus 10 may learn the manner of movement of the operation finger Z1 of a user by including time information of performance of coordinate correction and identification information of a scenario pattern for performing correction in the information to be stored in the coordinate correction DB 101, and accumulating such pieces of information. For example, the input control apparatus 10 may increase correction accuracy with respect to the manner of movement of the operation finger Z1 of a user by averaging of coordinate correction amounts or analysis of a histogram for each scenario pattern accumulated in the coordinate correction DB 101.

On the touch pad 2, contact of the operation finger Z1 is within a specific range of region. Accordingly, the number of equally divided regions described above may be determined based on the specific range of region where the operation finger Z1 contacts. Also, in an equally divided meshed region, the contact position correction unit 22 may calculate the rate of change in the correction amount based on differences among the coordinate correction amounts for division points that are adjacent in the up-down, left-right directions, and may store, in the coordinate correction DB 101, the calculated rate of change in association with an identification number of the meshed region. The input control apparatus 10 may calculate, based on the rate of change in the coordinate correction amount stored in the coordinate correction DB 101 and a coordinate position detected in the meshed region, the coordinate correction amount for the coordinate position.

In FIG. 5, after acquisition of the coordinate correction amount, the region defined by the routes R1a-R4a may be said to be the operation region of a user, for example, and a gap region between the region defined by the routes R1-R4 and the region defined by the routes R1a-R4a may be said to be a region where an operation is performed outside the operation region. For example, after acquisition of the coordinate correction amount, if a contact operation of a user is detected in the gap region, the input control apparatus 10 controls the piezoelectric driver circuit 2b such that a tactile sensation provided to the operation finger Z1 is changed. The user of the operation finger Z1 the tactile sensation on which is changed may change the contact position of the operation finger Z1 to the operation region defined by the routes R1a-R4a, for example.

Referring back to FIG. 1, the display control unit 23 controls a GUI element, such as a cursor displayed on the display 3, indicating the contact position of the operation finger Z1, based on the corrected coordinate information transferred from the contact position correction unit 22. The display position of a GUI element, such as a cursor displayed on the display 3, is controlled such that the GUI element is displayed at a display position indicated by the corrected coordinate information.

Also, the display control unit 23 performs display control so as to display, on the display 3, various types of contents provided via the AVN device or the like, and a GUI element or the like for performing coordinate correction for a touch-type operation. A GUI element or the like for performing coordinate correction for a touch-type operation is transferred from the correction instruction unit 24. Additionally, in the case where the display 3 includes a touch panel function, the display control unit 23 causes a GUI element displayed in the display region of the display device based on the coordinates of a detected contact position to function. For example, the display control unit 23 refers to the element management DB 102, and specifies a GUI element displayed at the detected contact position. Then, the display control unit 23 performs an operation function that is associated with the specified GUI element, such as an operation of pressing a button, turning on/off a switch, or increasing or decreasing the amount of control according to a slide operation.

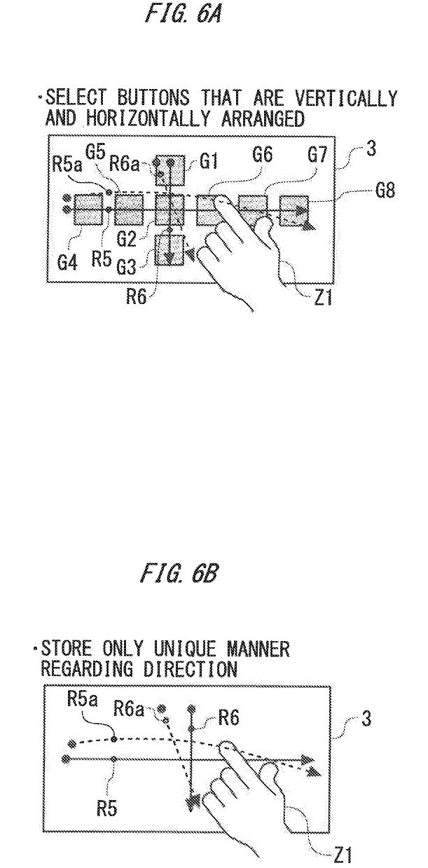

The correction instruction unit 24 issues a voice instruction or a display instruction for a GUI element according to a scenario of coordinate correction accompanying a touch-type operation. For example, the correction instruction unit 24 refers to the element management DB 102, specifies a GUI element that is displayed on the display 3 at the time of coordinate correction, and transfers the specified GUI element to the display control unit 23. Furthermore, the correction instruction unit 24 acquires data of a voice message or the like associated with the specified GUI element, and outputs the acquired data to the speaker 4 as an audio signal. A user performing a touch-type operation on the touch pad 2 performs an operation input for performing coordinate correction, according to the GUI element displayed on the display 3 or a voice message issued via the speaker 4, for example. With the input control apparatus 10, coordinate correction is performed on the contact position at the time of a touch-type operation based on an operation position, an operation track or the like detected based on the operation input for performing coordinate correction. In the following, an example scenario of operation correction will be described with reference to FIGS. 6A and 6B to FIG. 10.

<2. Example Correction Scenario>

### (Case 1)

FIGS. 6A and 6B illustrate examples of a scenario of a case of performing coordinate correction on an operation in each of a left-right direction and an up-down direction. Additionally, in the following description, a GUI element for performing coordinate correction is assumed to be displayed on the display 3. Also, a user is assumed to perform a touch-type operation input on the touch pad 2 while glancing at a display screen displayed on the display 3.

In FIG. 6A, the input control apparatus 10 that performs a correction scenario displays rectangular GUI elements G1-G8 on the display screen of the display 3. Additionally, there is no limitation on the shape of a GUI element to be displayed on the display screen of the display 3. The shape of a GUI element may be a triangle, a circle or a polygon such as a star.

For example, the input control apparatus 10 displays GUI elements G4, G5, G2, G6, G7, G8 in this order from the left end side to the right end side along the X-axis of the display region of the display 3. Also, for example, the input control apparatus 10 displays GUI elements G1, G2, G3 in this order from the upper end side to the lower end side along the Y-axis of the display region of the display 3. Then, the input control apparatus 10 issues, via a voice message or the like, an instruction to perform a slide operation along the GUI elements G4, G5, G2, G6, G7, G8 displayed in the left-right direction, for example. Also, the input control apparatus 10 issues, via a voice message or the like, an instruction to perform a slide operation along the GUI elements G1, G2, G3 displayed in the up-down direction, for example.

A user performing the touch-type operation performs a slide operation by bringing the operation finger Z1 into contact with the touch pad 2 and without separating the operation finger Z1 in contact from the surface of the touch pad 2. A slide operation is performed along the GUI elements G4, G5, G2, G6, G7, G8 displayed on the display 3, from the left end side toward the right end side. Also, the slide operation is performed along the GUI elements G1, G2, G3 displayed on the display 3, from the upper end side toward the lower end side.

For example, the input control apparatus 10 specifies a route R5a extending from the left end side to the right end side, and a route R6a extending from the upper end side to the lower end side, based on the tracks of coordinates of the contact positions detected via the touch pad 2. Then, the input control apparatus 10 performs coordinate correction such that the route R5a extending from the left end side to the right end side becomes a route R5. Also, the input control apparatus 10 performs coordinate correction such that the route R6a extending from the upper end side to the lower end side becomes a route R6. The coordinate correction amounts are stored in association with the operation tracks of the routes R5a, R6a. According to the input control apparatus 10, coordinate correction may be performed on an operation track of movement in the left-right direction along the X-axis of the touch pad 2, and on an operation track of movement in the up-down direction along the Y-axis, based on a plurality of GUI elements displayed on the display 3.

Additionally, as illustrated in FIG. 6B, the input control apparatus 10 may issue instructions regarding operation inputs in the left-right direction and the up-down direction by voice messages, without displaying GUI elements on the display 3. For example, the input control apparatus 10 issues, by voice messages, a slide operation instruction for horizontal movement from the left end to the right end of the touch pad 2, and a slide operation instruction for vertical movement from the upper end to the lower end. Then, the input control apparatus 10 may specify the routes R5a, R6a based on the tracks of touch-type operations performed after issuance of instructions by voice messages. The route R5 parallel to the X-axis and the route R6 parallel to the Y-axis may be calculated based on starting point coordinates and end point coordinates of the routes R5a, R6a, and the coordinate correction amounts for the calculated routes R5, R6 may be specified.

### (Case 2)

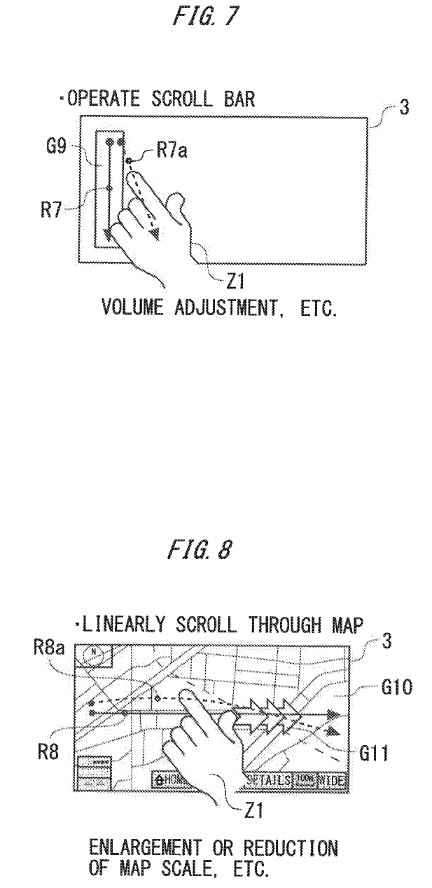

FIG. 7 illustrates an example of a scenario of a case of using, for operation correction, a display element that is associated with function control for the AVN device as a GUI element. As such a GUI element, a display element such as a scroll bar associated with a volume function for adjusting the audio volume may be cited, for example.

As illustrated in FIG. 7, the input control apparatus 10 that performs a correction scenario displays a scroll bar G9 on the display screen of the display 3. Additionally, the scroll bar G9 illustrated in FIG. 7 relates to an example of a movement operation in the up-down direction, but is also applicable to a movement operation in the left-right direction. Also, the display position of the scroll bar G9 is on the left end side of the display region of the display 3, but the display position may alternatively be at the center or on the right end side . For example, the input control apparatus 10 that performs a correction scenario may sequentially display the scroll bar G9 in the display region of the display 3, on the left end side, at the center, and on the right end side, and may perform coordinate correction at each display position.

For example, the input control apparatus 10 issues an instruction to operate the scroll bar G9 displayed on the display screen of the display 3, and to change the volume position from the maximum level to the minimum level. A user performing a touch-type operation brings the operation finger Z1 into contact with the touch pad 2, and performs a slide operation in the up-down direction without separating the operation finger Z1 in contact from the surface of the touch pad 2.

For example, the input control apparatus 10 specifies a route R7a extending from the upper end side to the lower end side along the scroll bar G9, based on the track of the coordinates of the contact position detected via the touch pad 2. Then, the input control apparatus 10 performs coordinate correction such that the route R7a extending from the upper end side to the lower end side along the scroll bar G9 becomes a route R7. The coordinate correction amount is stored in association with the operation track of the route R7a. According to the input control apparatus 10, coordinate correction on an operation track of movement in the up-down direction on the touch pad 2 may be performed based on an operation of a GUI element which is displayed on the display 3 and which can be operated.

### (Case 3)

FIG. 8 illustrates an example of a scenario of a case of using, for operation correction, a map screen called up by a navigation function provided by the AVN device. As illustrated in FIG. 8, the input control apparatus 10 that performs the correction scenario displays a map screen G10 that is called up by a navigation function provided by the AVN device on the display 3. For example, the input control apparatus 10 issues an instruction to perform a scroll operation on the map screen G10 displayed on the display 3. Additionally, the input control apparatus 10 may display a GUI element Gil indicating the scroll direction, by superimposing the GUI element Gil on the map screen G10. A user performing a touch-type operation brings the operation finger Z1 into contact with the touch pad 2, and performs a slide operation in the left-right direction without separating the operation finger Z1 in contact from the surface of the touch pad 2.

For example, the input control apparatus 10 specifies a route R8a extending from the left end side to the right end side along the map screen G10, based on the track of coordinates of the contact position detected via the touch pad 2. The input control apparatus 10 performs coordinate correction such that the route R8a extending from the left end side to the right end side along the map screen 10 becomes a route R8. Additionally, the route R8 is calculated as a route that extends from the starting point coordinates to the end point coordinates of the route R8a and that is parallel to the X-axis, for example. The input control apparatus 10 stores the coordinate correction amount for the route R8 in association with the operation track of the route R8a. According to the input control apparatus 10, coordinate correction on an operation track of movement in the left-right direction on the touch pad 2 may be performed based on an operation on the map screen G10 displayed on the display 3.

Additionally, for example, the input control apparatus 10 may issue an instruction for an operation such as pinch-out or pinch-in for scaling up or down the display range with respect to the map screen G10 displayed on the display 3, and may perform coordinate correction based on the detected movement track.

### (Case 4)

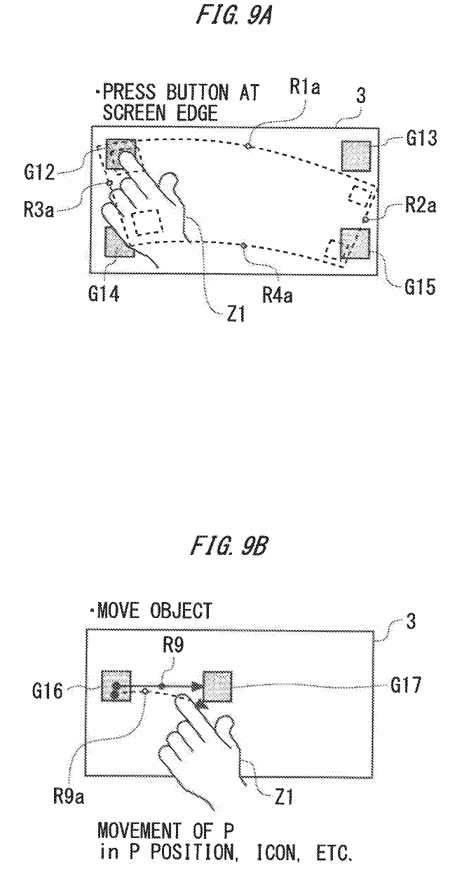

FIGS. 9A and 9B illustrate examples of a scenario of a case of performing coordinate correction with respect to a movable range of the operation finger Z1 at the time of a touch-type operation. In FIG. 9A, the input control apparatus 10 that performs a correction scenario displays rectangular GUI elements G12-G15 on the display screen of the display 3. Additionally, there is no limitation on the shape of the GUI elements G12-G15 to be displayed on the display screen of the display 3. The shapes of the GUI elements G12-G15 may be triangles, circles or polygons such as stars.

For example, the input control apparatus 10 displays the GUI element G12 at an upper left corner portion of the display region of the display 3, the GUI element G13 at an upper right corner portion of the display region of the display 3, the GUI element G14 at a lower left corner portion of the display region of the display 3, and the GUI element G15 at a lower left corner portion of the display region of the display 3. Then, the input control apparatus 10 issues an instruction to contact the GUI element G12 displayed at the upper left corner portion of the display 3, and to perform a slide operation from the GUI element G12 to the GUI element G13 displayed at the upper right corner portion of the display 3 and from the GUI element G12 to the GUI element G14 displayed at the lower left corner portion of the display 3.

Also, the input control apparatus 10 issues an instruction to contact the GUI element G13 displayed at the upper right corner portion of the display 3, and to perform a slide operation from the GUI element G13 to the GUI element G15 displayed at the lower right corner portion of the display 3. In the same manner, the input control apparatus 10 issues an instruction to contact the GUI element G14 displayed at the lower left corner portion of the display 3, and to perform a slide operation from the GUI element G14 to the GUI element G15 displayed at the lower right corner portion of the display 3.

Additionally, the GUI elements G12-G15 may be display elements that move on the display screen of the display 3 according to movement of the contact position of a user according to the slide operation. In such a case, for example, the input control apparatus 10 may issue an instruction to move the GUI element G12 displayed at the upper left corner portion of the display 3, and to superimpose it on the GUI element G13 displayed at the upper right corner portion.

For example, the input control apparatus 10 specifies the routes R1a, R2a, R3a, R4a described with reference to FIG. 5 from tracks of coordinates of the contact position detected via the touch pad 2. Additionally, the route R1a is an operation track extending from the GUI element G12 as the base point to the GUI element G13, and the route R2a is an operation track extending from the GUI element G13 as the base point to the GUI element G15. Also, the route R3a is an operation track extending from the GUI element G12 as the base point to the GUI element G14, and the route R4a is an operation track extending from the GUI element G14 as the base point to the GUI element G15. As described with reference to FIG. 5, the input control apparatus 10 performs coordinate correction on each route, and stores the coordinate correction amount in association with the operation track of each route. Additionally, coordinate correction on each route is described with reference to FIG. 5.

In FIG. 9A, GUI elements are displayed at positions such as the upper left corner portion, the lower left corner portion, the upper right corner portion, and the lower right corner portion which achieve the maximum area on the display 3 for specification of a movable range of the operation finger Z1. For example, the input control apparatus 10 may alternatively display, as the GUI elements, X lines combining a straight line connecting the upper left corner portion and the lower right corner portion and a straight line connecting the lower left corner portion and the upper right corner portion. The input control apparatus 10 is enabled to perform coordinate correction on operation tracks of the contact position of a user performing the slide operation along the X lines. The input control apparatus 10 may specify a maximum operation range of the user from the range of the contact position moving along the X lines.

Moreover, the X lines for specifying the movable range of the operation finger Z1 may be cross lines, for example. The input control apparatus 10 may display, as the GUI elements, cross lines combining a straight line connecting a middle position of the left side of the display 3 and a middle position of the right side of the display 3 and a straight line connecting a middle position of the upper side of the display 3 and a middle position of the lower side of the display 3, for example . The input control apparatus 10 is enabled to perform coordinate correction on operation tracks of the contact position of a user performing the slide operation along the cross lines. The input control apparatus 10 may specify a maximum operation range of the user from the range of the contact position moving along the cross lines.

Also, as illustrated in FIG. 9B, the input control apparatus 10 may display a GUI element such as an icon, and may move the displayed icon in a predetermined direction. In FIG. 9B, a GUI element G16 is an icon associated with activation of a predetermined application program, for example. Moreover, a GUI element G17 is a display element for operation of movement in a predetermined direction.

For example, the input control apparatus 10 issues an instruction to move the GUI element G16, which is an icon displayed on the display 3, to a display position where the GUI element G17 is displayed. Then, the input control apparatus 10 specifies a route R9a of the operation track of the icon movement operation based on the track of the coordinates of the contact position detected via the touch pad 2. The input control apparatus 10 performs coordinate correction such that the specified route R9a becomes a route R9 that connects the display position of the GUI element

G16 and the display position of the GUI element G17, and also, stores the coordinate correction amount in association with the route R9a. According to the input control apparatus 10, coordinate correction on an operation track of a user performing the touch-type operation may be performed based on an operation of moving the icon or the like displayed on the display 3.

### (Case 5)

For example, coordinate correction on an operation position or an operation track of a touch-type operation may be character input on a simple correction reference character such as “A”, “ [symbol] ” (Japanese Hiragana) , “ [symbol] ” (Japanese Katakana) , or “ [symbol] ” (Japanese Kanji). FIG. 10 illustrates an example of a scenario of a case of using character input on a Japanese Hiragana character “ [symbol] ”. For example, the input control apparatus 10 that performs the correction scenario displays a Japanese Hiragana character “ [symbol] ” as a correction reference on the display screen of the display 3, and also, issues an instruction to trace, along the character strokes, the correction reference character “ [symbol] ” (Japanese Hiragana) displayed on the screen. A user performing the touch-type operation moves the operation finger Z1 in contact with the touch pad 2 to trace the correction reference character “ [symbol] ” (Japanese Hiragana) displayed on the display 3.

For example, the input control apparatus 10 specifies a route R10a, which is the first character stroke of the correction reference character “ [symbol] ” (Japanese Hiragana), based on the track of the coordinates of the contact position detected via the touch pad 2. In the same manner, the input control apparatus 10 specifies a route R11a, which is the second character stroke of the correction reference character “ [symbol] ” (Japanese Hiragana), and a route R12a, which is the third character stroke. Each route of the correction reference character “ [symbol] ” (Japanese Hiragana) may be specified by separation of the operation finger Z1 in contact with the touch pad 2. Additionally, the input control apparatus 10 may issue an instruction to trace the next character stroke of the correction reference character “ [symbol] ” (Japanese Hiragana) on a per-stroke basis. The input control apparatus 10 may specify the character stroke, of the correction reference character “ [symbol] ” (Japanese Hiragana), corresponding to the movement track of the contact position detected after the instruction.

The input control apparatus 10 performs coordinate correction such that the route R10a, which is the first character stroke of the correction reference character “ [symbol] ” (Japanese Hiragana), becomes a route R10, and stores the coordinate correction amount in association with the movement track of the route R10a. In the same manner, the input control apparatus 10 performs coordinate correction such that the routes R11a, which is the second character stroke of the correction reference character “ [symbol] ” (Japanese Hiragana), and the route R12a, which is the third character stroke, become routes R11, R12, respectively, and also, stores the coordinate correction amounts in association with the movement tracks of the routes R11a, R12a. According to the input control apparatus 10, coordinate correction on an operation position or an operation track of the operation finger Z1 performing a touch-type operation may be performed based on an operation of tracing character strokes of a correction reference character displayed on the display 3.

<3. Process Flow>

In the following, an operation correction process according to the present embodiment will be described with reference to FIG. 11. FIG. 11 is a flowchart illustrating an example of an operation correction process provided by the input control apparatus 10. For example, the input control apparatus 10 of the present embodiment provides the operation correction process illustrated in FIG. 11 by the CPU 11 or the like reading out and executing various types of programs and various pieces of data stored in the auxiliary storage unit 13. Additionally, the CPU 11 or the like of the input control apparatus 10 performs the operation correction process by using the coordinate correction DB 101 and the element management DB 102 in the auxiliary storage unit 13 for reference or as storage destinations of data to be managed.

The process of the flowchart of FIG. 11 is started when an operation is performed on the touch pad 2 arranged at the center console or the like of a vehicle where the input control system 1 is mounted, for example. The input control apparatus 10 of the input control system 1 performs personal authentication for identifying a user, so as to correct the manner of movement of the operation finger Z1 unique to the user performing the touch-type operation detected via the touch pad 2 (S1).

Moreover, for example, the operation correction process illustrated in FIG. 11 may include options (hereinafter referred to also as correction modes) for calling up correction scenarios described with reference to FIGS. 5 to 10. For example, a GUI element for performing correction on a touch operation position is displayed on the display 3. The GUI element may be any element as long as a user can recognize the element as an element for performing correction on a touch operation position. The input control apparatus 10 receives an operation input on the GUI element displayed on the display 3, and may call up a correction scenario among those described with reference to FIGS. 5 to 10. The input control apparatus 10 may perform a correction process on a touch operation position based on the intention and timing of the user using the input control system 1.

Furthermore, the input control apparatus 10 may call up the correction scenarios described with reference to FIGS. 5 to 10 and perform correction on a touch operation position, with turning on of power (ignition) of the vehicle or the like where the input control system 1 is mounted as the trigger. The input control apparatus 10 has an advantage that a touch operation position can be corrected without fail at the time of use of the input control system 1 by a person who is on board.

Personal authentication by the input control apparatus 10 may be any authentication as long as each user performing a touch-type operation can be identified. For example, the input control apparatus 10 may use the protruding structure 2C, which is capable of fingerprint authentication, as described with reference to FIG. 3, or may use an iris authentication appliance or a voice print authentication appliance mounted on the vehicle, or may use password authentication via an USB or the display 3. The input control apparatus 10 acquires an authentication result based on a fingerprint image acquired by the protruding structure 2C provided on a side surface of the touch pad 2, or an authentication result acquired from an authentication appliance, as mentioned above, mounted on the vehicle, or based on password authentication via an USB or the display 3.

The input control apparatus 10 determines whether the user performing the touch-type operation can be specified based on the acquired authentication result (S2). In the case where the user, for whom processing is to be performed, is specified based on the authentication result (S2: YES), the input control apparatus 10 proceeds to the process in S3. On the other hand, in the case where the user, for whom processing is to be performed, is not specified based on the authentication result (S2: NO), the input control apparatus 10 proceeds to the process in S4.

In the process in S3, the input control apparatus 10 refers to the coordinate correction DB 101, for example, reads out the coordinate correction value of the user associated with the authentication information (user identification information) acquired by an authentication appliance, and temporarily stores the coordinate correction value in a predetermined region of the main storage unit 12. After the process in S3, the input control apparatus 10 proceeds to the process in S4.

In the process in S4, the input control apparatus 10 determines whether coordinate correction on an operation position or an operation track based on the touch-type operation of the user is necessary or not. For example, in the case where the user performing the contact operation via the touch pad 2 is specified in the process in S2, because the operation position or the operation track is corrected based on the coordinate correction amount stored in the coordinate correction DB 101, the input control apparatus 10 determines that coordinate correction is not necessary. In the same manner, in the case where the user performing the contact operation via the touch pad 2 cannot be specified in the process in S2, the input control apparatus 10 determines that the coordinate correction is necessary so as to perform coordinate correction, on the operation position or the operation track based on the touch-type operation, with respect to the manner of movement of the operation finger Z1 unique to the user.

Additionally, even in a case where the coordinate correction amount associated with a user is stored in the coordinate correction DB 101, the input control apparatus 10 may determine that coordinate correction is necessary, if the difference (elapsed time) between the current time information and the time information of the immediately preceding coordinate correction amount stored in the coordinate correction DB 101 is a specific period or more. A change in the accuracy due to the level of skill in the touch-type operation using the touch pad 2 may be reflected in the coordinate correction amount. Moreover, the input control apparatus 10 may regularly perform coordinate correction with respect to a predetermined correction scenario pattern selected in advance, on a daily, weekly or monthly basis, for example.

In the process in S4, in the case where coordinate correction is determined based on the conditions described above to be not necessary (S4: NO), the input control apparatus 10 ends the process in FIG. 11. On the other hand, in the case where coordinate correction is determined based on the conditions described above to be necessary (S4: YES), the input control apparatus 10 proceeds to the process in S5.

In the process in S5, the input control apparatus 10 issues an operation instruction to perform coordinate correction, on the operation position or the operation track based on the touch-type operation, with respect to the manner of movement of the operation finger Z1 unique to the user. The operation instruction to perform coordinate correction is described with reference to FIGS. 6A and 6B to FIG. 10. The operation instruction for coordinate correction may be a voice message issued to the operator via the speaker 4, or may be a display message displayed on the display 3.

In the process in S6, the input control apparatus 10 acquires an operation position or an operation track of the user detected according to the correction scenario for performing coordinate correction instructed by the process in S5. Then, the input control apparatus 10 performs coordinate correction on the acquired operation position or operation track (for example, the route Ra1-R12a) of the user based on the acquired operation position or operation track of the user and the correction reference track (for example, the route R1-R12) based on the reference image displayed in advance on the display 3 based on a correction scenario. Coordinate correction on the operation position or the operation track of the user has been described with reference to FIGS. 5 to 10.

In the process in S7, the input control apparatus 10 stores, in the coordinate correction DB 101, the coordinate correction amount for the operation position or the operation track of the user corrected by the process in S6. Information to be stored in the coordinate correction DB 101 has been described with reference to FIG. 5. Also, the input control apparatus 10 reflects the coordinate correction amount in the display position of a GUI element (such as a cursor) indicating the operation position of the operation finger Z1 displayed on the display 3. After the process in S7, the input control apparatus 10 ends the process of FIG. 11.

The input control apparatus 10 of the input control system 1 may perform correction of coordinates with respect to an operation position or an operation track based on a touch-type operation on a per-user basis by the process described above. According to the input control apparatus 10 of the input control system 1, coordinates can be corrected with respect to the manner of movement of the operation finger Z1 unique to a user. According to the input control apparatus 10, a deviation of the operation on the screen of the display 3 caused by the unique manner of movement of the operation finger performing the touch-type operation can be suppressed. The input control system 1 including the input control apparatus 10 enables an operation input intended by the user, and may increase the convenience of operation input at the time of touch-type operation.

<Others: Computer-Readable Recording Medium>

A program for causing a computer, any other machine or apparatus (hereinafter “computer or the like”) to realize one of the functions described above may be recorded in a computer-readable recording medium. The function can be provided by the computer or like reading and executing the program in the recording medium.

The recording medium that can be read by the computer or the like refers to a recording medium that accumulates information such as data and programs electrically, magnetically, optically, mechanically or by chemical action and that can be read by the computer or the like. Among such recording mediums, those that can be removed from the computer or the like include a flexible disc, a magneto-optic disc, a CD-ROM, a CD-R/W, a DVD, a Blu-ray disc, a DAT, an 8 mm tape, a memory card such as a flash memory, and the like. Also, a hard disk, a ROM, and the like may be cited as the recording mediums fixed in the computer or the like. Moreover, a solid state drive (SSD) may be used as a recording medium that can be removed from the computer or the like, and as a recording medium that is fixed in the computer or the like.

### REFERENCE SIGNS LIST

1 input control system
2 touch pad
2a piezoelectric element
2b piezoelectric driver circuit
3 display
4 speaker
10 input control apparatus
11 CPU
12 main storage unit
13 auxiliary storage unit
14 communication IF
15 input/output IF
16 connection bus
21 operation control unit
22 contact position correction unit
23 display control unit
24 correction instruction unit
101 coordinate correction DB
102 element management DB

1. An input control apparatus that receives a touch operation of a user, the input control apparatus comprising:
a storage unit that stores an actual touch operation position where a touch operation was performed with a predetermined position on an input apparatus as a target; and
a correction unit that corrects, based on a relationship between the actual touch operation position stored in the storage unit and the predetermined position, at least one of an input value at a time of reception of a touch operation for an operation target displayed on a display apparatus and a display content corresponding to the touch operation.

2. The input control apparatus according to claim 1, further comprising an instruction unit that instructs a user to perform an operation with the predetermined position on the input apparatus as a target,
wherein the storage unit stores the actual touch operation position when the touch operation of a user is performed in response to an instruction issued by the instruction unit.

3. The input control apparatus according to claim 1, wherein the predetermined position is a plurality of positions including an edge position, on the input apparatus, for receiving a touch operation of a user.

4. The input control apparatus according to claim 1, wherein the predetermined position is at least a part of a line that forms a maximum area on the input apparatus specified by a touch operation of a user.

5. The input control apparatus according to claim 1, wherein an arrangement position of the input apparatus is within a range allowing a touch operation from a driver's seat in a vehicle where the input apparatus is mounted.

6. The input control apparatus according to claim 1, wherein the input apparatus is one of a touch pad and a touch panel.

7. The input control apparatus according to claim 1, wherein the actual touch operation position stored in the storage unit is a track of a touch operation entailed in a scroll operation on a display screen displayed on the display apparatus.

8. The input control apparatus according to claim 1, wherein the actual touch operation position stored in the storage unit is a track of a touch operation entailed in a pinch-in operation or a pinch-out operation on a display screen displayed on the display apparatus.

9. The input control apparatus according to claim 1, wherein the actual touch operation position stored in the storage unit is a track of a touch operation performed along a character displayed on the display apparatus.

10. The input control apparatus according to claim 1, comprising a glance detection unit that detects a glance of a user at a time of touch operation on the input apparatus,
wherein the correction unit corrects control on a display content displayed on the display apparatus, under a condition that a glance direction of the user detected by the glance detection unit is not directed to the input apparatus.

11. An input control method performed by a computer of an input control apparatus that receives a touch operation of a user, the input control method comprising:
storing an actual touch operation position where a touch operation was performed with a predetermined position on an input apparatus as a target; and
correcting, based on a relationship between the actual touch operation position stored and the predetermined position, at least one of an input value at a time of reception of a touch operation for an operation target displayed on a display apparatus and a display content corresponding to the touch operation.

12. An input control system including an input apparatus that detects a touch operation of a user, a display apparatus, and an input control apparatus that receives the touch operation of the user detected by the input apparatus,
wherein the input control apparatus includes
a storage unit that stores an actual touch operation position where a touch operation was performed with a predetermined position on the input apparatus as a target, and
a correction unit that corrects, based on a relationship between the actual touch operation position stored in the storage unit and the predetermined position, at least one of an input value at a time of reception of a touch operation for an operation target displayed on the display apparatus and a display content corresponding to the touch operation.
